(19) United States
(12) Patent Application Publication
(10) Pub. No.: US 2014/0144693 A1
(43) Pub. Date: May 29, 2014

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Jae Hoon CHOI, Suwon (KR); Jong Kuk HONG, Suwon (KR)

(73) Assignee: SAMSUNG ELECTRO-MECHANICS CO., LTD., Suwon (KR)

(21) Appl. No.: 13/760,413

(22) Filed: Feb. 6, 2013

(30) Foreign Application Priority Data
Nov. 26, 2012 (KR) 10-2012-0134538

(51) Int. Cl. H05K 1/11; H05K 3/00

(52) U.S. Cl. CPC H05K 1/116; H05K 3/00
USPC 174/266; 427/97.3

(57) ABSTRACT

There is provided a printed circuit board, including: a core layer, a conductive via formed in a via hole of the core layer, an upper land formed on an upper surface of the conductive via, and a lower land formed on a lower surface of the conductive via, wherein a center of the upper land and a center of the lower land do not coincide with each other on a plane, so that the center of the upper land and the center of the lower land formed in the printed circuit board are arranged so as not to coincide with each other, thereby increasing durability of an insulating region against pressure in a wet process, and thus damage to the printed circuit board can be reduced.

### CROSS-REFERENCE TO RELATED APPLICATIONS

This application claims the priority of Korean Patent Application No. 10-2012-0134538 filed on Nov. 26, 2012, in the Korean Intellectual Property Office, the disclosure of which is incorporated herein by reference.

### BACKGROUND OF THE INVENTION

1. Field of the Invention

The present invention relates to a printed circuit board capable of reducing damage thereto by disposing a center of an upper land and a center of a lower land formed in the printed circuit board so as not to coincide with each other, and a method for manufacturing the same.

2. Description of the Related Art

Recently, the trend for multifunctional and high-speed electronic products has progressed rapidly. In order to cope with this trend, a heat producing element, such as a semiconductor chip, and a heat producing element-mounted printed circuit board, connecting the heat producing element and a main board to each other, have been also developed very rapidly. This trend is closely related to high speeds and high degrees of integration in printed circuit boards, and in order to satisfy these requirements, many improvements and developments in performance related to structures for lightening, slimming, simplifying, and allowing for compactness in a printed circuit board, as well as making circuits fine while implementing high degrees of reliability and allowing for high-speed signal transmissions are required.

Meanwhile, as electronic devices have become smaller, more highly dandified, and slimmer, semiconductor package boards have been actively studied to also be slimmer and more higher functional, and therefore, the need for slim printed circuit boards is also increasing.

Recently, in most cases, a thin plate of a printed circuit board has been manufactured by a roll to roll method. However, since improvements of the process, the roll to roll method, may damage the printed circuit board, a design aspect needs to be complemented.

In existing cases, lands are formed in positions in which a hole for transmitting electric signal between layers of the printed circuit board is generated. The upper and lower lands are placed in the same position, and clearances thereof, spaces surrounding the lands, are also placed in the same position.

As described above, when the upper and lower lands are placed in the same position, the printed circuit board may be damaged due to pressure from a liquid sprayed in a wet process during the manufacturing procedure of the printed circuit board.

In the case in which the process is undertaken such that the core layer has a thickness of 30 μm or less, only an insulating layer remains in the clearance, and thus the printed circuit board may be easily damaged in the wet process and during the handing procedure of the printed circuit board. Therefore, the printed circuit board needs to be prevented from being damaged during the process by allowing the upper and lower lands to cross each other in the clearance at which only the insulating layer remains.

### RELATED ART DOCUMENTS

(Patent Document 1) Korean Patent Laid-Open Publication No. 2000-0029352

(Patent Document 2) Korean Patent Laid-Open Publication No 2000-0022891

### SUMMARY OF THE INVENTION

An aspect of the invention provides a printed circuit board capable of reducing damage thereto by disposing a center of an upper land and a center of a lower land so as not to coincide with each other, and a method of manufacturing the same.

According to an aspect of the present invention, there is provided a printed circuit board, including: a core layer; a conductive via formed in a via hole of the core layer; an upper land formed on an upper surface of the conductive via; and a lower land formed on a lower surface of the conductive via, wherein a center of the upper land and a center of the lower land do not coincide with each other on a plane.

The core layer may have a thickness of 1 μm to 30 μm.

Here, at least one of the upper land and the lower land may have a circular shape.

Here, at least one of the upper land and the lower land may have an elliptical shape.

Here, at least one of the upper land and the lower land may have a rectangular shape.

Here, at least one of the upper land and the lower land may include protrusions.

Here, at least one of the upper land and the lower land may support at least 20% of an area of upper and lower clearances.

According to an aspect of the present invention, there is provided a method of manufacturing a printed circuit board, the method including: preparing a core layer; forming a conductive via in a via hole of the core layer; forming an upper land on an upper surface of the conductive via; and forming a lower land on a lower surface of the conductive via, wherein a center of the upper land and a center of the lower land do not coincide with each other on a plane.

The core layer may have a thickness of 1 μm to 30 μm.

Here, at least one of the upper land and the lower land may have a circular shape.

Here, at least one of the upper land and the lower land may have an elliptical shape.

Here, at least one of the upper land and the lower land may have a rectangular shape.

Here, at least one of the upper land and the lower land may include protrusions.

Here, at least one of the upper land and the lower land may support at least 20% of an area of upper and lower clearances.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a printed circuit board according to an embodiment of the invention;

FIG. 2 is a flow diagram showing a process for forming lands of a core layer according to the embodiment of the invention;

FIG. 3 illustrates a plane structure of the core layer according to the embodiment of the invention;

FIG. 4 illustrates a land structure including protrusions according to the embodiment of the invention;

FIG. 5 illustrates a land structure to which a design according to the embodiment of the invention is applied;

FIG. 6A illustrates that an upper land and a lower land according to the embodiment of the invention have the same shape, an elliptical shape, and leftward and rightward portions thereof overlap each other;

FIG. 6B illustrates that an upper land and a lower land according to the embodiment of the invention have protrusions having the same shape and cross each other;

FIG. 6C illustrates that an upper land and a lower land according to the embodiment of the invention have the same shape, a rectangular shape, and cross each other;

FIG. 6D illustrates that an upper land and a lower land according to the embodiment of the invention have the same shape, an elliptical shape, and leftward and rightward portions thereof overlap each other;

FIG. 6E illustrates that an upper land and a lower land according to the embodiment of the invention have protrusions having the same shape and cross each other;

FIG. 7A illustrates that an upper land has an elliptical shape and a lower land has a circular shape, according to the embodiment of the invention;

FIG. 7B illustrates that an upper land and a lower land according to the embodiment of the invention have the same shape, a circular shape, and only the upper land has protrusions;

FIG. 7C illustrates that an upper land and a lower land according to the embodiment of the invention have the same shape, a circular shape, and only the upper land has protrusions; and

FIG. 7D illustrates that an upper land has a circular shape and a lower land has a rectangular shape, according to the embodiment of the invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

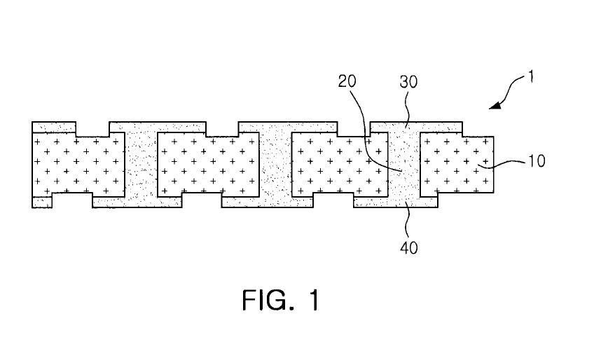

FIG. 1 is a cross-sectional view of a printed circuit board 1 according to an embodiment of the invention.

Referring to FIG. 1, the printed circuit board 1 may include: a core layer 10; a conductive via 20 formed in a via hole of the core layer 10; an upper land 30 formed on an upper surface of the conductive via 20; and a lower land 40 formed on a lower surface of the conductive via 20. Here, a center of the upper land 30 and a center of the lower land 40 are arranged so as not to coincide with each other.

The core layer 10 is a base member of the printed circuit board 1 according to the present invention and has a thickness of 1 μm to 30 μm. The core layer 10 may be formed of at least one of a metal including tungsten (W), molybdenum (Mo), and aluminum (Al), invar, Kovar, an alloy including nickel (Ni) and iron (Fe), and ceramic, but the material of the core layer 10 is not limited thereto.

Therefore, when the core layer 10 is inserted into the printed circuit board 1, hardness of the printed circuit board 1 is increased to thereby improve warpage characteristics and the heat radiation characteristics of the printed circuit board 1.

The upper land 30 and the lower land 40 may be formed to have the same shape or different shapes. At least one of the upper land 30 and the lower land 40 may have any shape, such as a circular shape, an elliptical shape, or a rectangular shape, and may have protrusions.

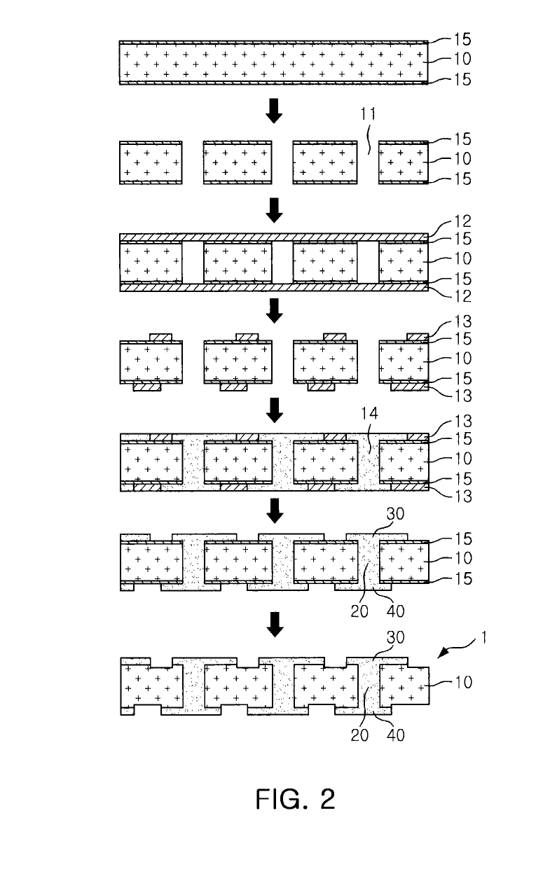

FIG. 2 is a flow diagram showing a process for forming the upper land 30 and the lower land 40 of the core layer 10 according to the embodiment of the invention.

Referring to FIG. 2, after the core layer 10 is prepared, a penetration hole 11 is formed in the core layer 10, and then a film 12 is applied to the core layer 10. In the related art, generally, the upper land 30 and the lower land 40 formed on an upper portion and a lower portion of the hole 50 are arranged at the same position. However, in the present invention, the upper land 30 and the lower land 40 are formed such that the centers of the upper land 30 and the lower land 40 are arranged so as not to coincide with each other.

Then, patterning is undertaken in such a manner that a portion of the film cured by ultraviolet irradiation (hereinafter, referred to as ‘a cured film 13’) remains as it is while an uncured portion of the film is removed, through a development process.

Then, after a plating layer (14) is formed in a state in which the cured film 13 remains, stripping is carried out to remove seed copper (15) on the core layer 10 through etching, to thereby form a circuit.

After the forming of the circuit, a routing process using a photo-solder resist (PSR) and surface treatment is carried out, to thereby manufacture the printed circuit board 1.

That is, in the preparing of the core layer 10 according to the related art, after forming of the circuit, when the upper and lower lands 30 and 40 have upper and lower symmetry, the printed circuit board may be easily damaged due to the pressure of liquid sprayed during a wet process. In order to solve the defect, the upper land 30 and the lower land 40 are formed such that the centers of the upper and lower lands 30 and 40 are arranged so as not to coincide with each other in the present invention, whereby clearances 60a and 60b do not coincide with each other, and thus, the printed circuit board can be prevented from being damaged. Here, the clearances 60a and 60b are margin spaces encasing the peripheries of the upper land 30 and the lower land 40, and include outside spaces of the upper land 30 and the lower land 40.

Meanwhile, in the case in which the upper and lower lands 30 and 40 are formed in an elliptical manner and are arranged to slightly overlap each other, such that the clearances 60a and 60b are designed to also overlap each other, or the clearances 60a and 60b have spare spaces, the upper and lower lands 30 and 40 may be formed to have protrusions 70 and 80 while the upper and lower lands 30 and 40 respectively have a circular shape or an elliptical shape.

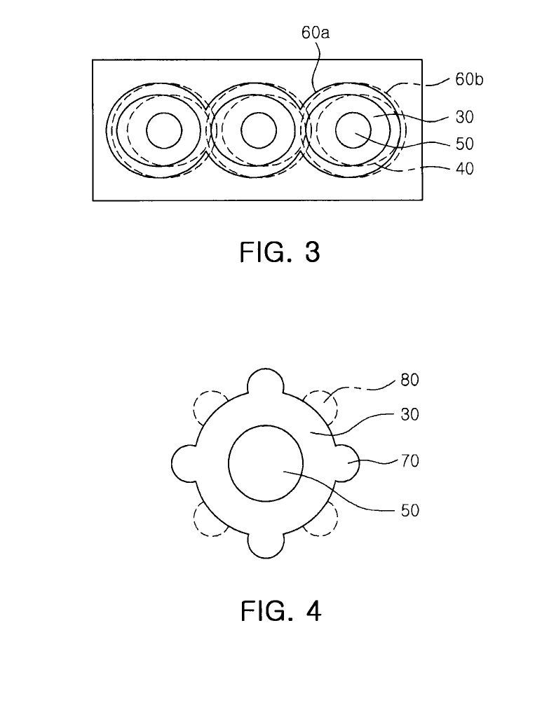

FIG. 3 shows a plane structure obtained by forming the upper land 30 and the lower land 40 of the core layer 10 according to the embodiment of the invention illustrated in FIG. 2. Referring to FIG. 3, in the case in which the core layer 10 is prepared in the method of the present invention, when the upper land 30 and the lower land 40 are formed such that the upper and lower lands 30 and 40 arranged on the upper portion and the lower portion of the hole 50 do not coincide with each other, the clearances 60a and 60b also do not coincide with each.

In this regard, according to the related art, in the case in which the core layer 10 is prepared, when the upper land 30 and the lower land 40 are placed at the same position on the upper portion and the lower portion of the hole 50, the clearances 60a and 60b are also placed at the same position. In this case, after the forming of the circuit, the clearances 60a and 60b may be vulnerable to the pressure of a liquid sprayed during a wet process and handling problems.

Therefore, upper and lower portions of the clearances 60a and 60b may have a copper layer formed thereon, so that an area of the clearances 60a and 60b in which only an insulating material is exposed, may allow for prevention of the printed circuit board from the damage thereto due to pressure in a wet process when the circuit is formed, and may remove damage caused at the time of operator's handling. In this case, even in the case in which one insulating layer is covered, the printed circuit board may be protected, and the thickness of the insulating layer may be 1 μm to 60 μm.

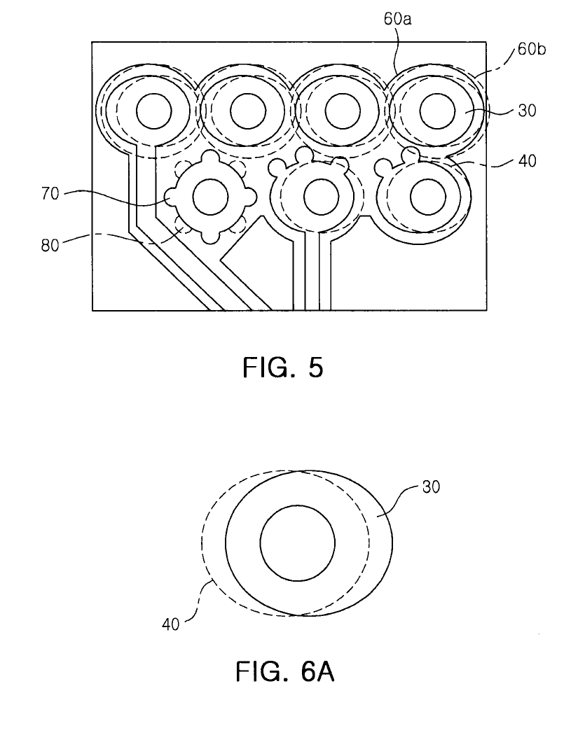

FIG. 4 shows a structure of the upper land 30 and the lower land 40 including protrusions according to the embodiment of the invention. In the case in which the clearance 60a and 60b have spare spaces, the clearances 60a and 60b may be complemented by forming the protrusions 70 and 80 on the upper land 30 and the lower land 40 while the upper land 30 and the lower land 40 respectively have a circular shape or an elliptical shape.

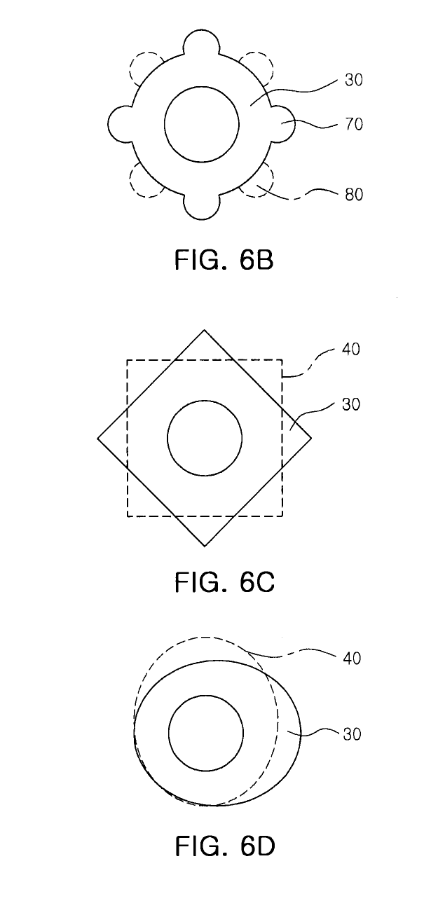

FIG. 5 shows a structure of the upper land 30 and the lower land 40 to which the design according to the embodiment of the invention is applied. The upper land 30 and the lower land 40 are formed such that the centers of the upper and lower lands 30 and 40 are arranged so as not to coincide with each other, whereby the clearances 60a and 60b do not coincide with each other, and the clearances 60a and 60b have spare spaces and thus include the protrusions 70 and 80.

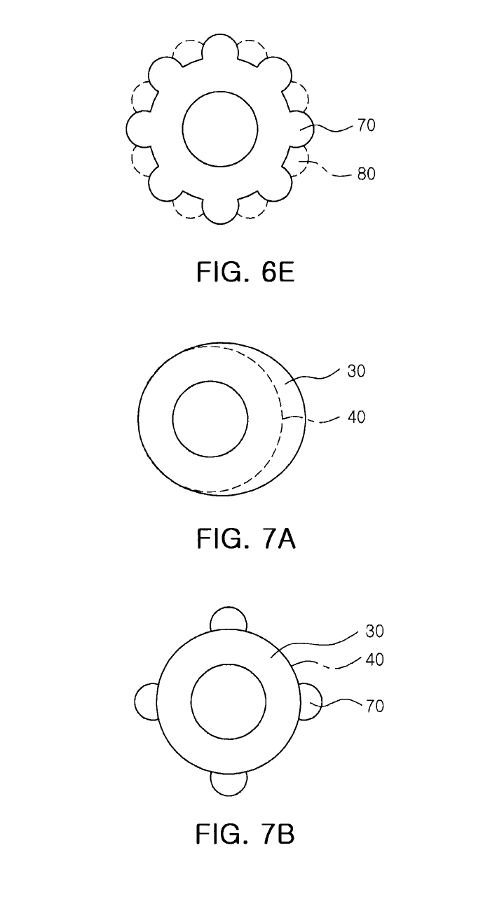

Referring to FIGS. 6A, 6B, 6C, 6D, and 6E, the upper land 30 and the lower land 40 have the same shape and the same area.

Considering a mathematical explanation of the above relationship, it is correct that a value obtained by subtracting an intersection between areas of the upper land 30 and the lower land 40 from a total area of the upper land 30 and the lower land 40 is “zero”, but since the centers of the upper land 30 and the lower land 40 are arranged so as not to coincide with each other, the value is not “zero,” regardless of the presence of the protrusions 70 and 80.

Therefore, even in the case in which the upper land 30 and the lower land 40 have the same area and the same shape, the centers of the upper land 30 and the lower land 40 are arranged so as not to coincide with each other, to thereby increase durability of an insulating region against pressure during a wet process, and thus damage to the printed circuit board can be reduced.

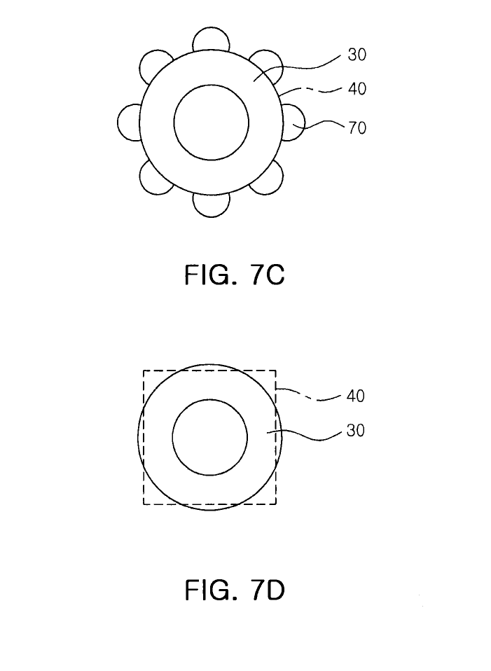

Referring to FIGS. 7A, 7B, 7C, and 7D, the upper land 30 and the lower land 40 have different shapes and different areas.

Considering a mathematical explanation of the above relationship, the value obtained by subtracting the intersection between areas of the upper land 30 and the lower land 40 from the total area of the upper land 30 and the lower land 40 is not “zero”.

A method of manufacturing a printed circuit board according to the present invention may include: preparing the core layer 10; forming the conductive via 20 in the via hole of the core layer 10; forming the upper land 30 on an upper surface of the conductive via 20; and forming the lower land 40 on a lower surface of the conductive via, wherein the centers of the upper land 30 and the lower land 40 are arranged so as not to coincide with each other on a plane.

In addition, at least one of the upper land 30 and the lower land 40 may have any of a circular shape, an elliptical shape, and a rectangular shape, and may include protrusions.

As set forth above, according to the embodiments of the invention, the center of the upper land and the center of the lower land formed in the printed circuit board are arranged so as not to coincide with each other, thereby increasing durability of the insulating region against pressure in a wet process, and thus damage to the printed circuit board can be reduced.

While the present invention has been shown and described in connection with the embodiments, it will be apparent to those skilled in the art that modifications and variations can be made without departing from the spirit and scope of the invention as defined by the appended claims.

What is claimed is:

1. A printed circuit board, comprising:
a core layer;
a conductive via formed in a via hole of the core layer;
an upper land formed on an upper surface of the conductive via; and
a lower land formed on a lower surface of the conductive via,
wherein a center of the upper land and a center of the lower land do not coincide with each other on a plane.

2. The printed circuit board of claim 1, wherein the core layer has a thickness of 1 μm to 30 μm.

3. The printed circuit board of claim 1, wherein at least one of the upper land and the lower land has a circular shape.

4. The printed circuit board of claim 1, wherein at least one of the upper land and the lower land has an elliptical shape.

5. The printed circuit board of claim 1, wherein at least one of the upper land and the lower land has a rectangular shape.

6. The printed circuit board of claim 1, wherein at least one of the upper land and the lower land includes protrusions.

7. The printed circuit board of claim 1, wherein at least one of the upper land and the lower land supports at least 20% of an area of upper and lower clearances.

8. A method of manufacturing a printed circuit board, the method comprising:
preparing a core layer;
forming a conductive via in a via hole of the core layer;
forming an upper land on an upper surface of the conductive via; and
forming a lower land on a lower surface of the conductive via,
wherein a center of the upper land and a center of the lower land do not coincide with each other on a plane.

9. The method of claim 8, wherein the core layer has a thickness of 1 μm to 30 μm.

10. The method of claim 8, wherein at least one of the upper land and the lower land has a circular shape.

11. The method of claim 8, wherein at least one of the upper land and the lower land has an elliptical shape.

12. The method of claim 8, wherein at least one of the upper land and the lower land has a rectangular shape.

13. The method of claim 8, wherein at least one of the upper land and the lower land includes protrusions.

14. The method of claim 8, wherein at least one of the upper land and the lower land supports at least 20% of an area of upper and lower clearances.
